(19) United States
(12) Patent Application Publication
(10) Pub. No.: US 2019/0010046 A1
(43) Pub. Date: Jan. 10, 2019

(54) PACKAGING STRUCTURE AND PACKAGING METHOD OF MEMS CHIP AND ASIC CHIP

(71) Applicant: China Wafer Level CSP Co., Ltd., Suzhou (CN)

(72) Inventor: Zhiqi Wang, Suzhou (CN)

(73) Assignee: China Wafer Level CSP Co., Ltd., Suzhou (CN)

(21) Appl. No.: 16/019,730

(22) Filed: Jun. 27, 2018

(30) Foreign Application Priority Data
Jul. 6, 2017 (CN) 201710546745.1
Jul. 6, 2017 (CN) 201720814617.6

(51) Int. Cl. B81B 7/00; B81C 3/00; B81C 1/00; H01L 23/00; H01L 23/522

(52) U.S. Cl. CPC B81B 7/007; B81B 7/0058; B81C 3/001; B81C 1/00095; B81B 2207/093; H01L 24/97; H01L 24/16; H01L 23/5226; B81B 2207/096; H01L 24/09

(57) ABSTRACT

A packaging structure integrated with an MEMS chip and an ASIC chip and a packing method are provided. The packaging structure includes: an MEMS chip, an ASIC chip, a first solder bump and a cover plate. The MEMS chip has a front surface and an opposite back surface. The ASIC chip has a front surface and an opposite back surface. The front surface of the ASIC chip is laminated and fixed to the back surface of the MEMS chip, and the ASIC chip is electrically connected to the MEMS chip. The first solder bump is arranged on a side of the ASIC chip facing away from the MEMS chip, and electrically connects to an external circuit. The cover plate includes an accommodating cavity. The MEMS chip is located in the accommodating cavity and the cover plate is hermetically connected to the ASIC chip.

### CROSS REFERENCE TO RELATED APPLICATION

The present application claims the priority to Chinese Patent Applications No. 201710546745.1, titled “PACKAGING STRUCTURE AND PACKAGING METHOD OF MEMS CHIP AND ASIC CHIP” and No. 201720814617.6, titled “PACKAGING STRUCTURE OF MEMS CHIP AND ASIC CHIP” filed on Jul. 6, 2017 with the State Intellectual Property Office of the PRC, both of which are incorporated herein by reference in their entireties.

### FIELD

The present disclosure relates to the technical field of semiconductor devices, and in particular to a packaging structure and a chip packaging method.

### BACKGROUND

The Micro-Electro-Mechanical System (MEMS) is an industrial technology in which the microelectronic technology is combined with the mechanical engineering, and the technology is applied within a micrometer range. The MEMS is a new research and development field in which the mixing effects of multiple physical fields have to be considered at the same time. Compared with a conventional mechanical system, a size of the MEMS is smaller, the largest size of the MEMS does not exceed one centimeter, even just a few microns, and the thickness of the MEMS is much less. The Application Specific Integrated Circuit (ASIC) is considered to be an integrated circuit designed for a specific object in the integrated circuit field. The feature of the ASIC is based on requirements of specific users. The ASIC has advantages such as a smaller volume, a lower power consumption, a higher reliability, a better performance, a better confidentiality and a lower cost, as compared with the universal integrated circuit in mass production.

For the MEMS and the ASIC, a generation technology similar to the integrated circuit may be adopted. The mature technology and process of the integrated circuit can be sufficiently used to carry out mass and low-cost production to manufacture the MEMS chip and the ASIC chip with a high performance. A packaging structure integrated with the MEMS chip and the ASIC chip develops a new technical field and industry. A micro-sensor, a micro-actuator, a micro-component, a micro-mechanical optical device, a vacuum microelectronic device, and a power electronic device fabricated based on the packaging structure are widely applied in fields of aviation, aerospace, automobile, biomedicine, environmental monitoring, military and almost all fields that people are exposed to.

In the conventional technology, the general packaging structure of the MEMS chip and the ASIC chip is complex, and has a high manufacturing cost. Therefore, a problem to be urgently solved in the field of semiconductor devices is how to provide a packaging structure of the MEMS chip and the ASIC chip with a simple structure and a low manufacturing cost and a packaging method thereof.

### SUMMARY

In order to solve the above problems, a packaging structure and a chip packaging method are provided according to the present disclosure, so that the packaging structure of the MEMS chip and the ASIC chip is simple and has a low manufacturing cost.

In order to achieve the above objects, the following technical solutions are provided according to the present disclosure.

A packaging structure integrated with an MEMS chip and an ASIC chip is provided, which includes: an MEMS chip, an ASIC chip, a first solder bump, and a cover plate. The MEMS chip has a front surface and a back surface opposite to each other. The ASIC chip has a front surface and a back surface opposite to each other. The front surface of the ASIC chip is laminated and fixed to the back surface of the MEMS chip, and the ASIC chip is electrically connected to the MEMS chip. The first solder bump is arranged on a side of the ASIC chip facing away from the MEMS chip, where the first solder bump is configured to electrically connect to an external circuit. The cover plate includes an accommodating cavity. The cover plate is arranged on the ASIC chip, the MEMS chip is located in the accommodating cavity and the cover plate is hermetically connected to the ASIC chip.

In an embodiment, in the above packaging structure, the back surface of the MEMS chip is provided with a second solder bump, the front surface of the MEMS chip is provided with a first contact pad electrically connected to the second solder bump. The ASIC chip includes a coupling circuit configured to electrically connect to the second solder bump.

In an embodiment, in the above packaging structure, the back surface of the MEMS chip is provided with a first via hole penetrating the MEMS chip, and the first contact pad is exposed from the first via hole. A first electrical connection structure is formed in the first via hole, where the first electrical connection structure is electrically connected to the first contact pad and the second solder bump.

In an embodiment, in the above packaging structure, the first electrical connection structure is a first conductive plug.

In an embodiment, in the above packaging structure, the first electrical connection structure includes a first rewiring layer arranged in the first via hole.

In an embodiment, in the above packaging structure, an aperture of the first via hole remains unchanged in a direction from the MEMS chip to the ASIC chip; or the aperture of the first via hole is gradually increased in a direction from the MEMS chip to the ASIC chip; or the first via hole includes: a groove arranged on the back surface of the MEMS chip, where a depth of the groove is less than a thickness of the MEMS chip; and a through hole located in the groove and penetrating the MEMS chip.

In an embodiment, in the above packaging structure, a second contact pad is arranged on the front surface of the ASIC chip and a second via hole penetrating the ASIC chip is arranged on the back surface of the ASIC chip, and the second contact pad is exposed from the second via hole. A second connection structure is formed in the second via hole, where the second connection structure is electrically connected to the second contact pad and the first solder bump.

In an embodiment, in the above packaging structure, the second connection structure is a second conductive plug.

In an embodiment, in the above packaging structure, the second conductive plug is directly electrically connected to the first solder bump or is electrically connected to the first solder bump via a printed circuit arranged on the back surface of the ASIC chip.

In an embodiment, in the above packaging structure, the second connection structure includes a second rewiring layer arranged in the second via hole.

In an embodiment, in the above packaging structure, an aperture of the second via hole remains unchanged in a direction from the MEMS chip to the ASIC chip; or the aperture of the second via hole is gradually increased in a direction from the MEMS chip to the ASIC chip; or the second via hole includes: a groove arranged on the back surface of the MEMS chip, where a depth of the groove is less than a thickness of the ASIC chip; and a through hole located in the groove and penetrating the ASIC chip.

In an embodiment, in the above packaging structure, in a direction perpendicular to the MEMS chip and the ASIC chip, a size of the MEMS chip is less than a size of the ASIC chip.

In an embodiment, in the above packaging structure, the back surface of the ASIC chip is thinned and the back surface of the thinned ASIC chip is provided with a reinforcement layer.

A packaging method for forming the packaging structure described above is further provided according to the present disclosure, where the packaging method includes:

providing a wafer, where the wafer includes multiple ASIC chips arranged in an array, a cutting trench is arranged between two adjacent ASIC chips among the multiple ASIC chips; the ASIC chip has a front surface and a back surface;

laminating and fixing an MEMS chip to the front surface of the ASIC chip, where the MEMS chip has a front surface and a back surface opposite to each other; the front surface of the ASIC chip is laminated and fixed to the back surface of the MEMS chip, and the ASIC chip is electrically connected to the MEMS chip;

providing a substrate laminated and fixed to the wafer; and

forming a first solder bump on the back surface of the ASIC chip, where the first solder bump is configured to electrically connect to an external circuit; and

cutting along the cutting trench to form multiple packaging structures,

where after the cutting, the substrate is divided into multiple cover plates; each of the multiple packaging structures has one of the multiple cover plates; in the above packaging structure, the cover plate is arranged on the ASIC chip and includes an accommodating cavity, the MEMS chip is located in the accommodating cavity, and the cover plate is hermetically connected to the ASIC chip.

In an embodiment, in the above packaging method, the laminating and fixing an MEMS chip to the front surface of the ASIC chip includes:

arranging a first contact pad on the front surface of the MEMS chip, and arranging a second solder bump electrically connected to the first contact pad on the back surface of the MEMS chip; arranging a second contact pad electrically connected to the first solder bump on the front surface of the ASIC chip; and laminating and fixing the MEMS chip to the front surface of the ASIC chip through soldering the second solder bump and the second contact pad.

In an embodiment, in the above packaging method, the forming the first solder bump on the back surface of the ASIC chip includes:

forming a second via hole penetrating the ASIC chip on the back surface of the ASIC chip, where the second contact pad is exposed from the second via hole;

forming a second electrical connection structure in the second via hole; and

forming the first solder bump electrically connected to the second electrical connection structure on the back surface of the ASIC chip.

In an embodiment, in the above packaging method, the forming a second electrical connection structure in the second via hole includes:

forming a second conductive plug or a second rewiring layer in the second via hole.

In an embodiment, the packaging method further includes:

thinning a surface on a side of the wafer facing away from the MEMS chip.

In an embodiment, after the thinning process, the method further includes:

forming a reinforcement layer on the side of the wafer facing away from the MEMS chip.

A chip packaging method for forming the packaging structure described above is further provided according to the present disclosure, where the chip packaging method includes:

providing a wafer, where the wafer includes multiple ASIC chips arranged in an array, a cutting trench is arranged between two adjacent ASIC chips among the multiple ASIC chips; the ASIC chip has a front surface and a back surface;

laminating and fixing an MEMS chip to the front surface of the ASIC chip, where the MEMS chip has a front surface and a back surface opposite to each other; the front surface of the ASIC chip is laminated and fixed to the back surface of the MEMS chip, and the ASIC chip is electrically connected to the MEMS chip;

arranging a cover plate on a side of the MEMS chip facing away from the ASIC chip, where the cover plate includes an accommodating cavity and is arranged on the ASIC chip, the MEMS chip is located in the accommodating cavity, and the cover plate is hermetically connected to the ASIC chip;

forming a first solder bump on the back surface of the ASIC chip, where the first solder bump is configured to electrically connect to an external circuit; and

cutting along the cutting trench to form multiple packaging structures.

It may be known from the above description that, with the packaging structure and the chip packaging method provided according to the technical solution of the present disclosure, the MEMS chip is electrically connected to the external circuit via the first solder bump arranged on the side of the ASIC chip facing away from the MEMS chip, and the MEMS chip is hermetically protected through the cover plate. The packaging structure of the MEMS chip and the ASIC chip is simple and has a low manufacturing cost.

### BRIEF DESCRIPTION OF THE DRAWINGS

In order to more clearly illustrate technical solutions of the embodiment of the present disclosure or the conventional technologies, the drawings to be used in the description of the embodiments or the conventional technology are briefly described below. Apparently, the drawings only describe some embodiments of the present disclosure, and other drawings may be obtained by those skilled in the art based on these drawings without any creative work.

FIG. 1 is a schematic structural diagram of a packaging structure of an MEMS chip and an ASIC chip according to an embodiment of the present disclosure;

FIG. 2 is a schematic structural diagram of an MEMS chip according to an embodiment of the present disclosure;

FIG. 3 is a schematic structural diagram of another MEMS chip according to an embodiment of the present disclosure;

FIG. 4 is a schematic structural diagram of another MEMS chip according to an embodiment of the present disclosure;

FIG. 5 is a schematic structural diagram of another MEMS chip according to an embodiment of the present disclosure;

FIG. 6 is a schematic flow chart of a chip packaging method according to an embodiment of the present disclosure;

FIGS. 7 to 16 are schematic diagrams showing principles of a chip packaging method according to an embodiment of the present disclosure; and

FIG. 17 is a schematic flow chart of another chip packaging method according to an embodiment of the present disclosure.

### DETAILED DESCRIPTION OF EMBODIMENTS

Hereinafter, the technical solutions according to the embodiments of the present disclosure will be described clearly and completely in conjunction with the drawings in the embodiment of the present disclosure. Apparently, the described embodiments are only a few rather than all of embodiments of the present disclosure. Any other embodiments obtained by those skilled in the art based on the embodiments of the present disclosure without any creative work fall within the scope of protection of the disclosure.

In order to make the objectives, features and advantages of the embodiment of the present disclosure more apparent and easy understanding, the present disclosure will be described in detail as follows in conjunction with the drawings and the specific embodiments.

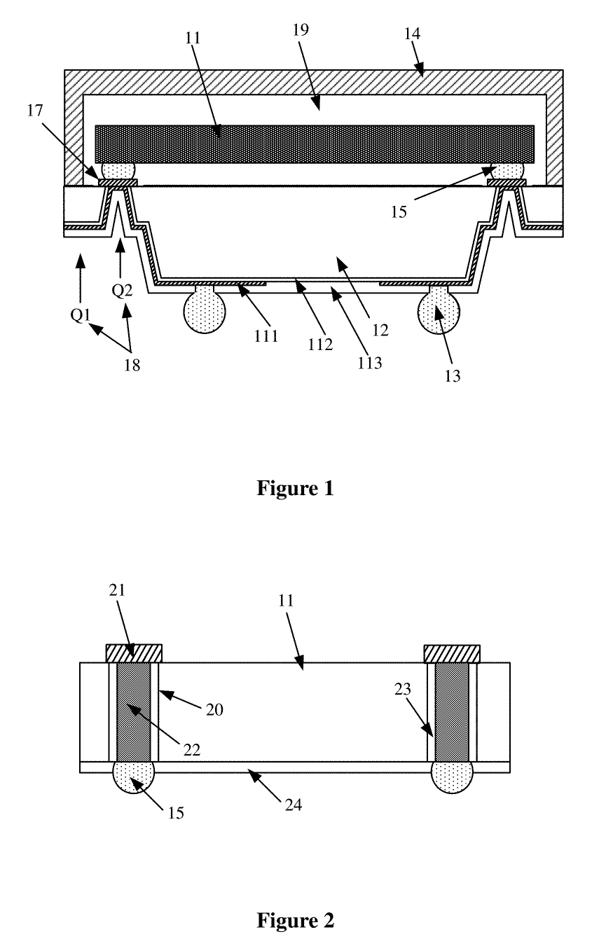

Reference is made to FIG. 1 which is a schematic structural diagram of a packaging structure of an MEMS chip and an ASIC chip according to an embodiment of the present disclosure. The packaging structure includes an MEMS chip 11, an ASIC chip 12 and a cover plate 14. The MEMS chip 11 has a front surface and a back surface opposite to each other. The ASIC chip 12 has a front surface and a back surface opposite to each other. The front surface of the ASIC chip 12 is laminated and fixed to the back surface of the MEMS chip 11, and the ASIC chip 12 is electrically connected to the MEMS chip 11. A first solder bump 13 is arranged on a side of the ASIC chip 12 facing away from the MEMS chip 11, and the first solder bump 13 is configured to electrically connect to an external circuit. The cover plate 14 includes an accommodating cavity 19 and is arranged on the ASIC chip 12. The cover plate 14 is hermetically connected to the ASIC chip 12 and is configured to seal the MEMS chip 11.

In the packaging structure according to the embodiment of the present disclosure, the MEMS chip 11 is electrically connected to the external circuit via the first solder bump 13 arranged on a side of the ASIC chip 12 facing away from the MEMS chip 11, and a seal protection is performed to the MEMS chip 11 by the cover plate 14. The packaging structure of the MEMS chip 11 and the ASIC chip 12 is simple and has a low manufacturing cost.

Optionally, the first solder bump 13 may be a contact pad or a solder ball. According to the embodiment shown in FIG. 1, the first solder bump 13 is the solder ball. The first solder bump 13 may be formed on the side of the ASIC chip 12 facing away from the MEMS chip 11 through a through-silicon-via (TSV) process.

As shown in FIG. 1, for facilitating an electrical connection between the MEMS chip 11 and the ASIC chip 12, the back surface of the MEMS chip 11 is provided with a second solder bump 15. The ASIC chip 12 includes a coupling circuit configured to electrically connect to the second solder bump 15.

The second solder bump 15 may also be formed on a side of the MEMS chip 11 facing the ASIC chip 12 through the TSV process.

Optionally, the front surface of the MEMS chip 11 is provided with a first contact pad. The first contact pad is electrically connected to the second solder bump 15. The contact pad is not shown in FIG. 1.

In order to achieve an electrical connection between the first contact pad and the second solder bump 15, a first via hole penetrating the MEMS chip 11 may be arranged on the back surface of the MEMS chip 11, and the first contact pad is exposed from the first via hole. A first electrical connection structure is arranged in the first via hole to electrically connect the first contact pad and the second solder bump 15. The first electrical connection structure may be a first conductive plug or a first rewiring layer arranged in the first via hole.

An aperture of the first via hole remains unchanged in a direction from the MEMS chip 11 to the ASIC chip 12. In this case, the first via hole is defined as a straight hole. The first via hole may be a round hole, a square hole or a triangular hole and so on.

Alternatively, the aperture of the first via hole is gradually increased in a direction from the MEMS chip 11 to the ASIC chip 12. In this case, the first via hole is defined as a trapezoidal via hole. The trapezoidal hole may be a truncated cone or a frustum of a prism.

Alternatively, the first via hole includes: a groove arranged on the back surface of the MEMS chip 11, where a depth of the groove is less than a thickness of the MEMS chip 11; and a through hole located in the groove and penetrating the MEMS chip 11. In this case, the first via hole is defined as a double stepped hole.

Reference is made to FIG. 2, which is a schematic structural diagram of an MEMS chip according to an embodiment of the present disclosure. As shown in FIG. 2, the MEMS chip 11 includes a first via hole 20 penetrating the MEMS chip 11. The first via hole 20 is provided with a first conductive plug 22 which is configured to electrically connect the second solder bump 15 and a first contact pad 21. An insulating layer 23 is arranged between the first conductive plug 22 and the MEMS chip 11. A surface on a side of the MEMS chip 11 facing away from the first contact pad 21 is provided with a solder mask 24. An opening is arranged at a position in the solder mask 24 corresponding to the first conductive plug 22, and the second solder bump 15 is arranged in the opening. In this case, the second solder bump 15 is electrically connected to the contact pad 21 via the first conductive plug 22, so as to electrically connect to the first contact pad 21. The first contact pad 21 may be directly electrically connected to the first conductive plug 22 or connected to the first conductive plug 22 via a printed circuit arranged on the front surface of the MEMS chip 11. The second solder bump 15 may be directly electrically connected to the first conductive plug 22, or connected to the first conductive plug 22 via a printed circuit arranged on the back surface of the MEMS chip 11.

Multiple first contact pads 21 are arranged on the front surface of the MEMS chip 11. Optionally, the contact pads may be arranged, in a form of two columns, at two sides of the front surface of the MEMS chip 11 opposite to each other. In the embodiment shown in FIG. 2, the aperture of the first via hole 20 remains unchanged in a direction from the MEMS chip 11 to the ASIC chip 12, that is, the first via hole is a straight hole. In a case where the first contact pad 21 is electrically connected to the second solder bump 15 via the first conductive plug 22, the first via hole 20 may also be the above trapezoidal hole or double stepped hole. In this case, it is necessary to provide the matched first conductive plug 22 based on a shape of the first via hole 20.

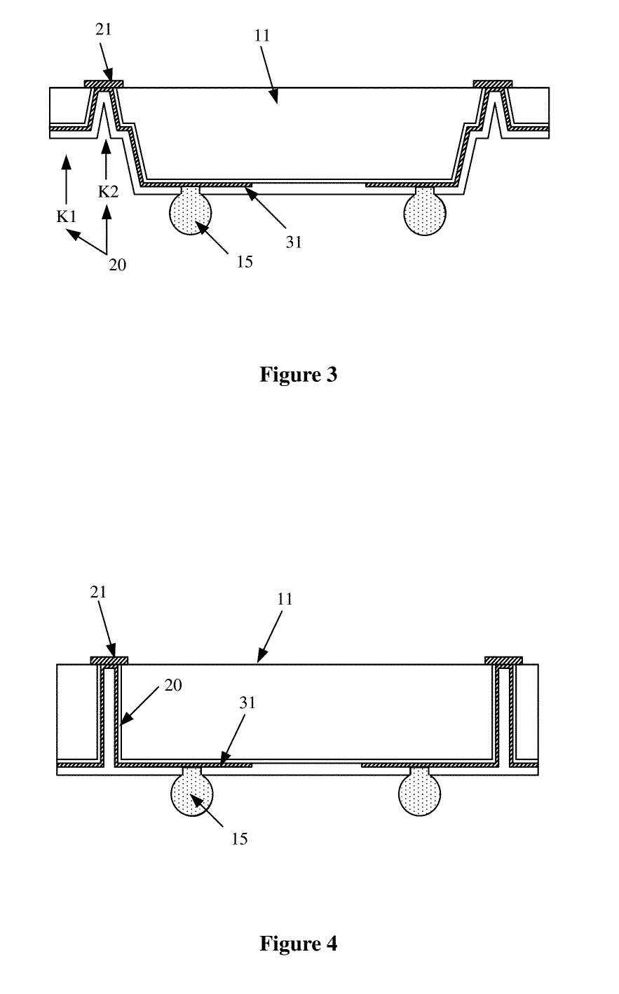

Reference is made to FIG. 3, which is a schematic structural diagram of another MEMS chip according to an embodiment of the present disclosure. The MEMS chip 11 includes a first via hole 20 penetrating the MEMS chip 11. The MEMS chip 11 shown in FIG. 3 differs from the MEMS chip 11 shown in FIG. 2 in that the first via hole 20 shown in FIG. 3 is a double stepped hole. The double stepped hole includes a groove K1 not penetrating the MEMS chip 11 and a through hole K2 located in the groove K1 and penetrating the MEMS chip 11.

In a case where the multiple first contact pads 21 are arranged in two columns, the back surface of the MEMS chip 11 is provided with two grooves K1 corresponding to the two columns of first contact pads 21. Multiple through holes K2 are arranged in the grooves K1, the first contact pads 21 are exposed from the through holes K2, and there is a one-to-one correspondence between the first contact pads 21 and the through holes. A first rewiring layer 31 is arranged in the first via holes 20, and is configured to electrically connect the first contact pad 21 and the second solder bump 15. Specifically, the second solder bump 15 is electrically connected to the first contact pad 21 via the first rewiring layer 31.

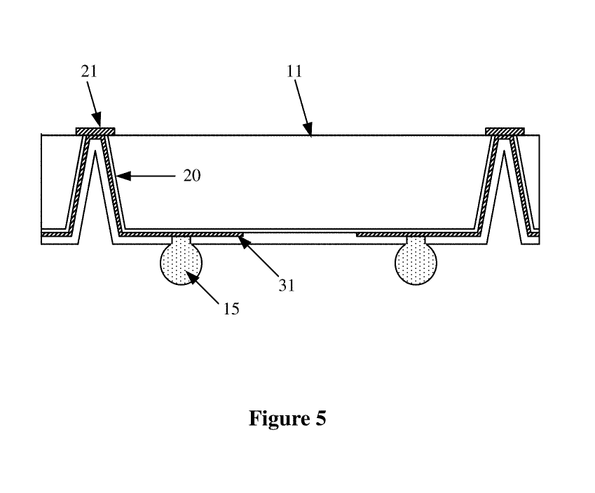

Reference is made to FIG. 4, which is a schematic structural diagram of another MEMS chip according to an embodiment of the present disclosure. As shown in FIG. 4, the MEMS chip 11 includes a first via hole 20 penetrating the MEMS chip 11. The embodiment shown in FIG. 4 differs from the embodiment shown in FIG. 3 in that the first via hole 20 shown in FIG. 4 is a straight hole. Similarly, the first contact pad 21 is electrically connected to the second solder bump 15 via the first rewiring layer 31 arranged in the first via hole 20 in FIG. 4.

Reference is made to FIG. 5, which is a schematic structural diagram of another MEMS chip according to an embodiment of the present disclosure. As shown in FIG. 5, the MEMS chip 11 includes a first via hole 20 penetrating the MEMS chip 11. The embodiment shown in FIG. 5 differs from the embodiment shown in FIG. 3 in that the first via hole 20 shown in FIG. 5 is a trapezoidal hole. Similarly, the first contact pad 21 is electrically connected to the second solder bump 15 via the first rewiring layer 31 arranged in the first via hole 20 according to the embodiment shown in FIG. 5.

As shown in FIG. 1, in the above packaging structure according to the embodiment of the present disclosure, a second via hole 18 penetrating the ASIC chip 12 is arranged on the back surface of the ASIC chip 12, so that the second solder bump 15 is electrically connected to the first solder bump 13. Specifically, a second contact pad 17 is arranged on the front surface of the ASIC chip 12, and the first solder bump 13 is electrically connected to the contact pad 17 via a second connection structure arranged in the second via hole 18, thereby electrically connecting to the second solder bump 15. The second connection structure is electrically connected to the second contact pad 17 and the first solder bump 13. The second connection structure is a second conductive plug or a second rewiring layer arranged in the second via hole 18.

The second via 18 hole and the first via hole 20 are implemented in the same manner. Similarly, the second via hole 18 may be a straight hole, a trapezoidal hole or a double stepped hole.

In a case where the second via hole 18 is the straight hole, an aperture of the second via hole 18 remains unchanged in a direction from the MEMS chip 11 to the ASIC chip 12.

In a case where the second via hole 18 is the trapezoidal hole, the aperture of the second via hole 18 is gradually increased in a direction from the MEMS chip 11 to the ASIC chip 12.

In a case where the second via hole 18 is the double stepped hole, the second via hole 18 includes: a groove Q1 arranged on the back surface of the ASIC chip 12, where a depth of the groove Q1 is less than a thickness of the ASIC chip 12; and a through hole Q2 located in the groove Q1 and penetrating the ASIC chip 12.

In the embodiment shown in FIG. 1, the ASIC chip 12 is provided with the second via hole 18 penetrating the ASIC chip 12. The second rewiring layer 111 is arranged in the second via hole 18, and is configured to electrically connect the second contact pad 17 and the first solder bump 13. In this case, a back surface structure of the ASIC chip 12 is the same as a back surface structure of the MEMS chip 11 shown in FIG. 3. An insulating layer 112 is arranged between the second rewiring layer 111 and the ASIC chip 12. A surface of the second rewiring layer 111 is covered by a solder mask 113. The first solder bump 13 is electrically connected to the second rewiring layer 111 via an opening located in the solder mask 113, so as to electrically connect to the second contact pad 17, thereby electrically connecting to the second solder bump 15 via the second contact pad 17. The back surface of the ASIC chip 12 is a surface on the side of the ASIC chip 12 facing away from the MEMS chip 11. The back surface of the MEMS chip 11 is a surface on the side of the MEMS chip 11 facing the ASIC chip 12.

In the embodiment shown in FIG. 1, the second via hole 18 is the double stepped hole, which includes the groove Q1 not penetrating the ASIC chip 12, and the through hole Q2 located in the groove Q1 and penetrating the ASIC chip 12.

In other embodiments, the contact pad 17 may be electrically connected to the first solder bump 13 through the second conductive plug arranged in the second via hole 18. In this case, the first solder bump 13 is electrically connected to the second solder bump 15.

The second conductive plug is electrically connected to the first solder bump 13 via a printed circuit arranged on the back surface of the ASIC chip 12. Alternatively, the second conductive plug may also be directly electrically connected to the first solder bump 13. In this case, a back surface structure of the ASIC chip 12 is the same as a back surface structure of the MEMS chip 11 shown in FIG. 2, which is not illustrated herein. In a case where the second conductive plug is arranged in the second via hole 18, the second via hole may also be the trapezoidal hole or the double stepped hole. The second via holes 18 with different shapes are provided with the second conductive plugs with different shapes.

In other embodiments, in a case where the second via hole 18 is a straight hole, the first solder bump 13 may be electrically connected to the contact pad 17 via the second rewiring layer arranged in the second via hole 18, thereby electrically connecting to the second solder bump 15. In this case, a back surface structure of the ASIC chip 12 is the same as a back surface structure of the MEMS chip 11 shown in FIG. 4, which is not illustrated herein.

In other embodiments, the second via hole 18 may also be a trapezoidal hole. The second via hole 18 is provided with the second rewiring layer configured to electrically connect the second solder bump 15 and the first solder bump 13. Specifically, the first solder bump 13 is electrically connected to the second contact pad 17 via the second rewiring layer, thereby electrically connecting to the second solder bump 15. In this case, the back surface structure of the ASIC chip 12 is the same as the back surface structure of the MEMS chip 11 shown in FIG. 5, which is not illustrated herein.

In the packaging structure according to the embodiment of the present disclosure, in a direction perpendicular to the MEMS chip 11 and the ASIC chip 12, a size of the MEMS chip 11 is less than a size of the ASIC chip 12. That is to say, a vertical projection of the MEMS chip 11 on the ASIC chip 12 totally falls in a coverage of the ASIC chip 12. In this way, the size of the MEMS chip 11 is reduced, an integration level of the packaging structure is improved and a manufacturing cost is reduced.

In the packaging structure according to the embodiment of the present disclosure, the cover plate 14 includes an accommodating cavity 19 on a side facing the MEMS chip 11. The MEMS chip 11 is located in the accommodating cavity 19. The accommodating cavity 19 is an evacuated accommodating cavity, or the accommodating cavity 19 is filled with a sealant. In a case where the accommodating cavity 19 is an evacuated accommodating cavity, an inner wall of the accommodating cavity 19 is coated with a desiccant to prolong a service life. The desiccant is not shown in FIG. 1. In order to ensure stability of the MEMS chip 11 and the ASIC chip 12, an insulating adhesive layer is arranged between the MEMS chip 11 and the ASIC chip 12. The insulating adhesive layer is not shown in FIG. 1. Optionally, the cover plate 14 is a PCB substrate, a glass substrate, a metal substrate, a semiconductor substrate or a polymer flexible substrate.

In a case where the chip is packaged according to the conventional technology, it is necessary to perform the thinning process to the chip in order to obtain the packaging structure with a thinner thickness. Specifically, the chip may be thinned by a mechanical grinding, a chemical etching and other methods. A mechanical strength of the thinned chip is weak.

In the embodiment of the present disclosure, in order to ensure that the packaging structure has a thin thickness and a high mechanical strength, the back surface of the ASIC chip 12 is thinned, and the back surface of the thinned ASIC chip 12 is provided with a reinforcement layer. The mechanical strength of the reinforcement layer is higher than the mechanical strength of the ASIC chip 12. In this way, the ASIC chip 12 may be further thinned based on the conventional technology, and the mechanical strength is increased through the reinforcement layer arranged on the side of the ASIC chip 12 facing away from the MEMS chip 11. The packaging structure can have good mechanical strength while the thickness of the ASIC chip 12 is greatly reduced.

That is to say, as compared with the packaging structure in the conventional technology, for the packaging structure according to the embodiment of the present disclosure, further thinning process can be performed to reduce the thickness of the ASIC chip 12, so that the ASIC chip 12 is thinner; in addition, the mechanical strength of the thinned ASIC chip 12 is compensated by the reinforcement layer with better mechanical strength, thereby achieving a light and thin packaging structure. Optionally, the reinforcement layer may be made of a plastic packaging material. The reinforcement layer includes an opening in which the first solder bump 13 is arranged, so as to electrically connect the first solder bump 13 and the coupling circuit.

Similarly, in order to further reduce the thickness of the packaging structure and ensure the mechanical strength thereof, the back surface of the MEMS chip 11 is thinned and the back surface of the thinned MEMS chip 11 is provided with a reinforcement layer. The mechanical strength of the reinforcement layer is higher than the mechanical strength of the MEMS chip 11.

In the packaging structure according to the embodiment of the present disclosure, the MEMS chip 11 is electrically connected to an external circuit via the first solder bump 13 arranged on the side of the ASIC chip 12 facing away from the MEMS chip 11, and a sealing protection is performed on the MEMS chip 11 through the cover plate 14. The packaging structure of the MEMS chip 11 and the ASIC chip 12 is simple and has a low manufacturing cost.

In addition, in the packaging structure according to the embodiment of the present disclosure, the second solder bump 15 is formed on the back surface of the MEMS chip 11 through a TSV process, and the first solder bump 13 is formed on the back surface of the ASIC chip 12 through the TSV process. The MEMS chip 11 and the ASIC chip 12 may be directly soldered to achieve an electrical coupling without solder leads and so on, thereby reducing the sizes of the MEMS chip 11 and the ASIC chip 12 and improving the integration level.

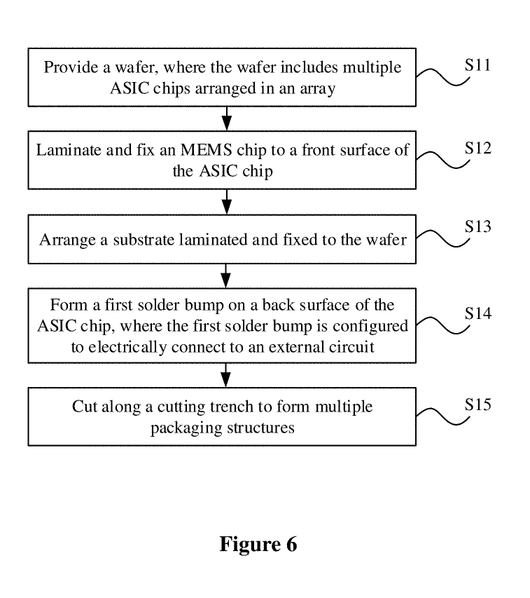

Based on the above packaging structure embodiments, a chip packaging method for fabricating the above packaging structure is further provided according to another embodiment of the present disclosure. The packaging method is shown in FIG. 6.

Reference is made to FIG. 6, which is a schematic flow chart of a chip packaging method according to an embodiment of the present disclosure. The chip packaging method includes following steps S11 to S15.

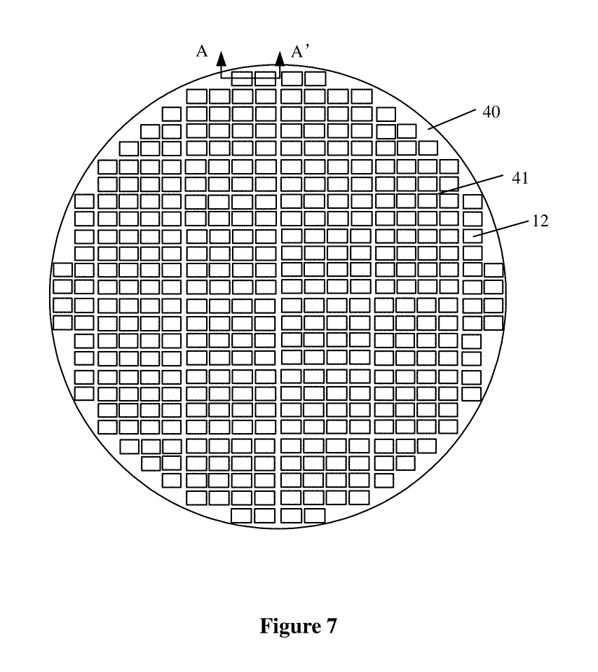

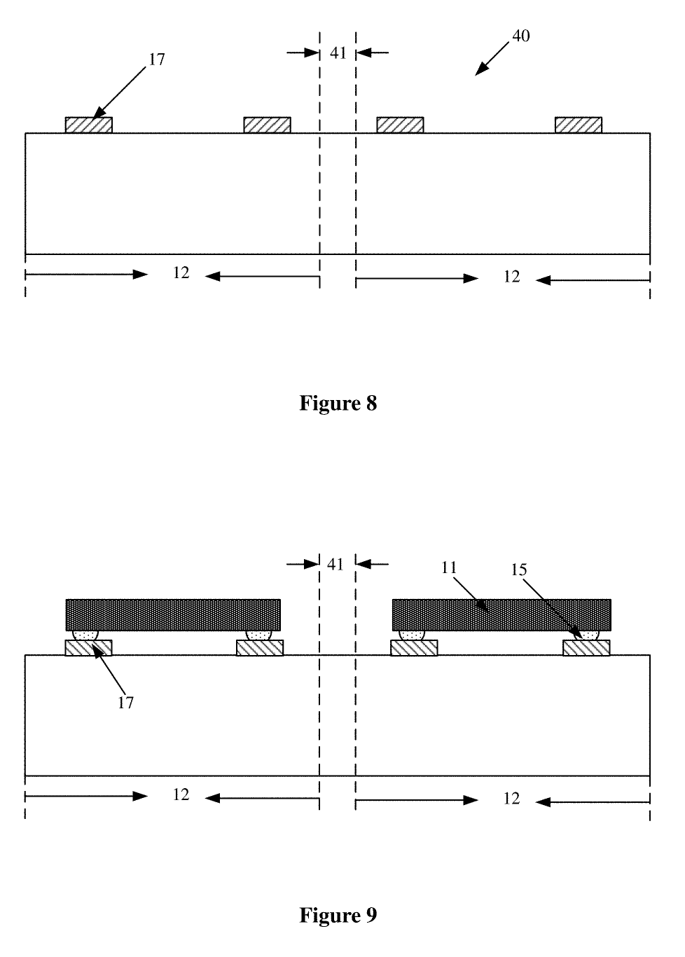

In step S11, as shown in FIGS. 7 and 8, a wafer 40 is provided. FIG. 7 is a schematic top view of the wafer 40. FIG. 8 is a section diagram of FIG. 7 in a direction AA′.

The wafer 40 includes multiple ASIC chips 12 arranged in an array, and a cutting trench 41 is arranged between two adjacent ASIC chips 12. The ASIC chip 12 has a front surface and a back surface. The front surface of the ASIC chip 12 is provided with a second contact pad 17.

In step S12, as shown in FIG. 9, an MEMS chip 11 is laminated and fixed to the front surface of the ASIC chip 12.

The MEMS chip 11 has a front surface and a back surface opposite to each other. The front surface of the ASIC chip 12 is laminated and fixed to the back surface of the MEMS chip 11, and the ASIC chip 12 is electrically connected to the MEMS chip 11. The back surface of the MEMS chip 11 is provided with a second solder bump 15 electrically connected to the second contact pad 17. The second solder bump 15 is formed on the back surface of the MEMS chip 11 through a TSV process.

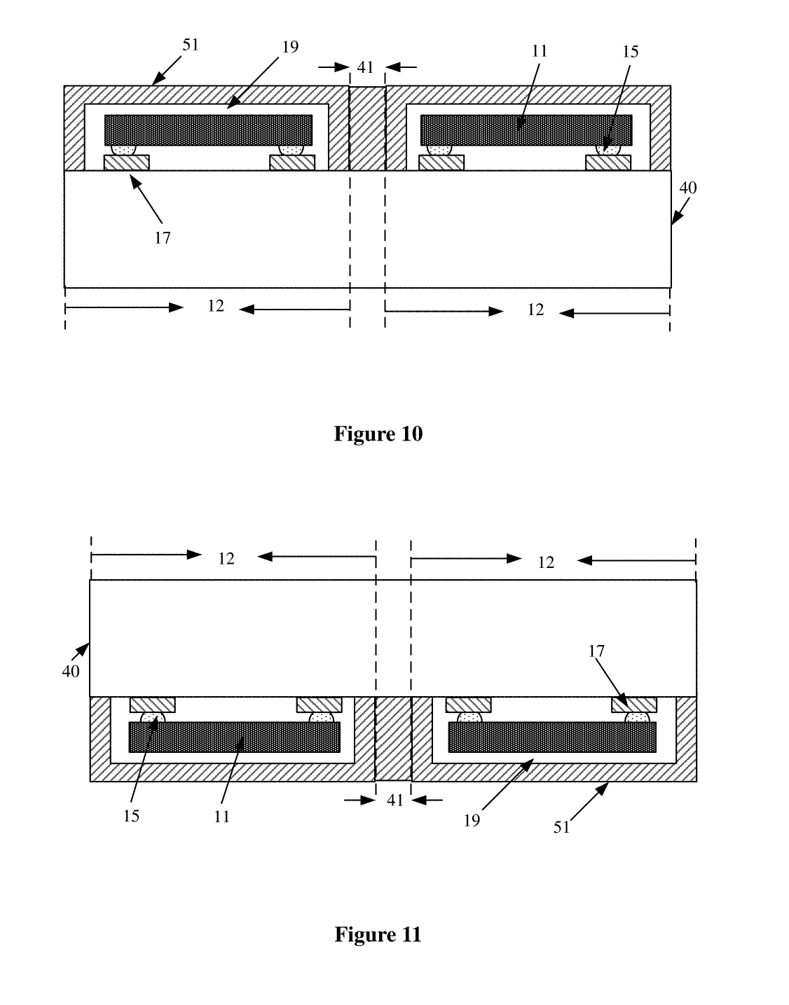

In step S13, as shown in FIG. 10, a substrate 51 laminated and fixed to the wafer 40 is provided.

An accommodating cavity 19 is provided in a region in the substrate 51 corresponding to each MEMS chip 11, and the MEMS chip 11 is located in the accommodating cavity 19.

In step S14, as shown in FIGS. 11 to 16, a first solder bump 13 is formed on the back surface of the ASIC chip 12. The first solder bump 13 is configured to electrically connect to an external circuit.

First, as shown in FIG. 11, the ASIC chip is inverted, the substrate 51 functions as a bottom protective substrate for the wafer 40 to perform the subsequent TSV process without providing a separate protective substrate.

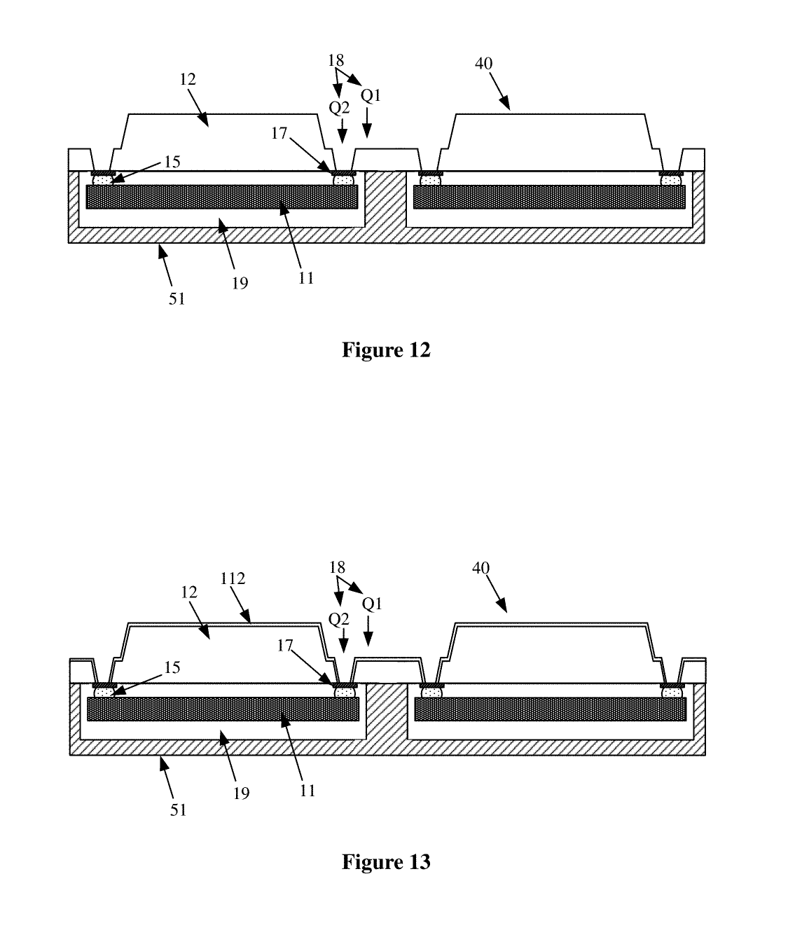

Then, as shown in FIG. 12, a second via hole 18 penetrating the ASIC chip 12 is formed. Before forming the second via hole 18, the back surface of the wafer 40 may be thinned. In the present disclosure, a reinforcement layer may be arranged in the subsequent process, so that the wafer 40 is greatly thinned, thereby ensuring a mechanical strength of the wafer 40 while reducing the thickness of the wafer 40. It is assumed that the second via hole 18 is a double stepped via hole. First, a groove Q1 not penetrating the ASIC chip is formed, then a through hole Q2 penetrating the ASIC chip is formed in the groove Q1. The second contact pad 17 on the other side of the ASIC chip is exposed from the through hole Q2.

Furthermore, as shown in FIG. 13, an insulating layer 112 covering the back surface of the wafer 40 is formed, and the insulating layer 112 covers a sidewall of the second via hole 18. A bottom of the second via hole 18 is provided with an opening from which the contact pad 17 is exposed.

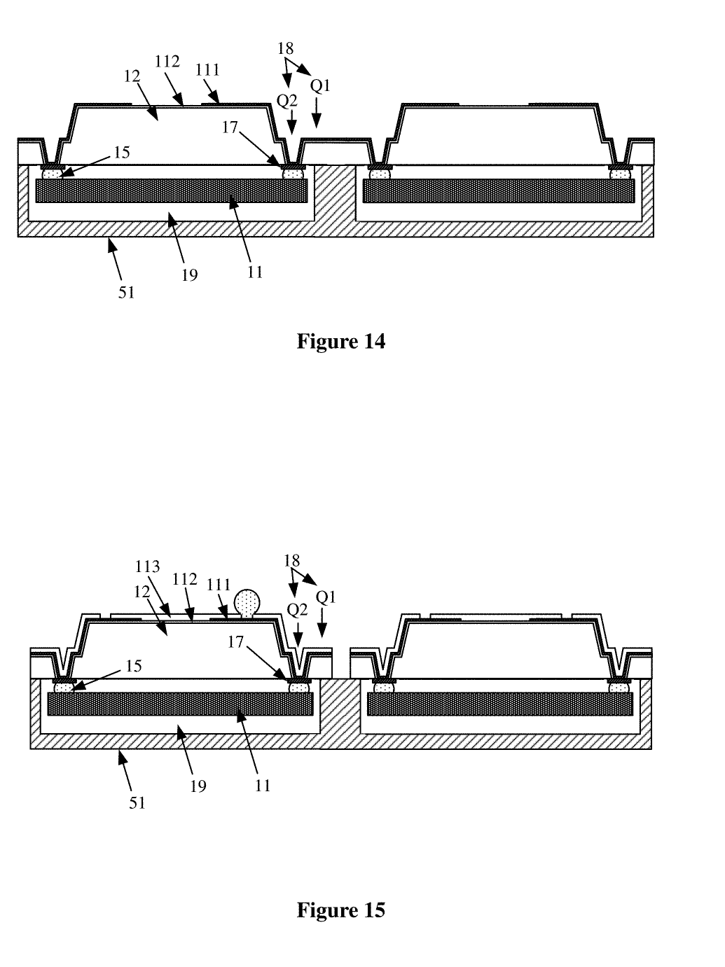

Furthermore, as shown in FIG. 14, a second rewiring layer 111 is formed on a surface of the insulating layer 112. The second rewiring layer 111 covers the bottom of the second via hole 18, and extends to the outside of the second via hole 18.

Furthermore, as shown in FIG. 15, a solder mask 113 is formed on a surface of the second rewiring layer 111. A surface of the solder mask 113 is provided with an opening.

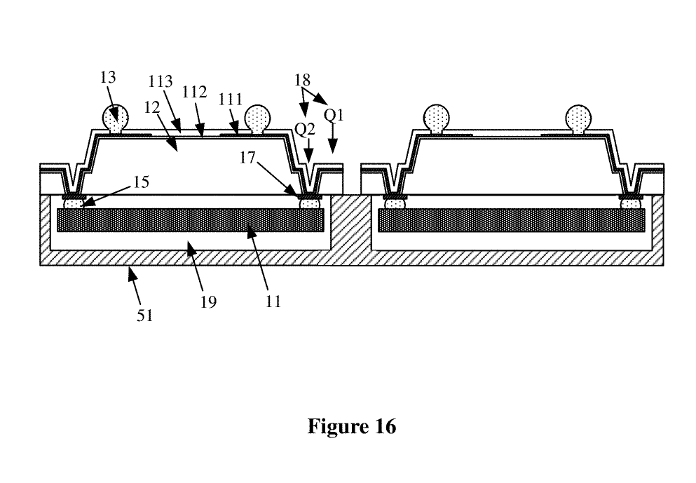

Finally, as shown in FIG. 16, a first solder bump 13 is arranged at the opening of the solder mask 113.

In step S15, cutting is performed along the cutting trench 41 to form multiple packaging structures.

After the cutting, the formed packaging structure is as shown in FIG. 1. The substrate 51 is divided into multiple cover plates 14. Each packaging structure includes one cover plate 14. In the packaging structure, a periphery of the cover plate 14 is laminated and fixed to a periphery of the ASIC chip 12, and the cover plate 14 is configured to seal the MEMS chip 11.

In the embodiment shown in FIG. 16, the first solder bump 13 is electrically connected to the second contact pad 17 via the second rewiring layer 111 located in the second via hole 18 penetrating the ASIC chip 12, and thus electrically connected to the second solder bump 15. In this case, the process of laminating and fixing an MEMS chip 11 to the front surface of the ASIC chip 12 includes: arranging a second solder bump 15 on the back surface of the MEMS chip 11, the ASIC chip 12 including a coupling circuit; and electrically connecting the second solder bump 15 and the first solder bump 13 via the coupling circuit. The coupling circuit includes the above second electrical connection structure. Specifically, the front surface of the MEMS chip 11 is provided with a first contact pad and the back surface of the MEMS chip 11 is provided with the second solder bump 15 electrically connected to the first contact pad. The front surface of the ASIC chip 11 is provided with the second contact pad 17 electrically connected to the first solder bump 13. The MEMS chip 11 is laminated and fixed to the front surface of the ASIC chip 12 through soldering the second solder bump 15 and the second contact pad 17.

In the embodiment shown in FIG. 16, the coupling circuit includes the second rewiring layer 111. In this case, the process of forming the first solder bump 13 on the back surface of the ASIC chip 12 includes: forming the second via hole 18 penetrating the ASIC chip 12 on the back surface of the ASIC chip 12, where the second contact pad 17 on the front surface of the ASIC chip is exposed from the second via hole 18; forming the second electrical connection structure in the second via hole 18; and forming the first solder bump 13 electrically connected to the second electrical connection structure on the back surface of the ASIC chip 11.

In the embodiment shown in FIG. 16, the second via hole 18 is a double stepped hole. The second electrical connection structure includes: the second rewiring layer 111 arranged in the second via hole 18. The second contact pad 17 and the first solder bump 13 are electrically connected via the second rewiring layer 111.

In other embodiments, the process of forming the first solder bump 13 on the back surface of the ASIC chip 12 includes: electrically connecting the second contact pad 17 and the first solder bump 13 via a second conductive plug arranged in the second via hole 18.

As described above, the second via hole 18 may be a straight hole, a trapezoidal hole or a double stepped hole.

As described above, in order to fabricate the packaging structure with a thinner thickness and a better mechanical strength, the above chip packaging method further includes: thinning a surface on a side of the wafer 40 facing away from the MEMS chip 11. After the thinning process, the method further includes: forming a reinforcement layer on the side of the wafer 40 facing away from the MEMS chip 11. The reinforcement layer may be formed before the first solder bump 13 is fabricated. A specific position of the reinforcement layer on the side of the ASIC chip 12 facing away from the MEMS chip 11 is not limited, and a position of the reinforcement layer relative to other layers on the back surface of the ASIC chip 12 may be set as needed.

In the above chip packaging method, the packaging structure of the MEMS chip 11 and the ASIC chip 12 is formed by adopting a wafer level packaging process. The process is simple, the cost is low, and the packaging structure is thin, and has the good mechanical strength and the high integration level.

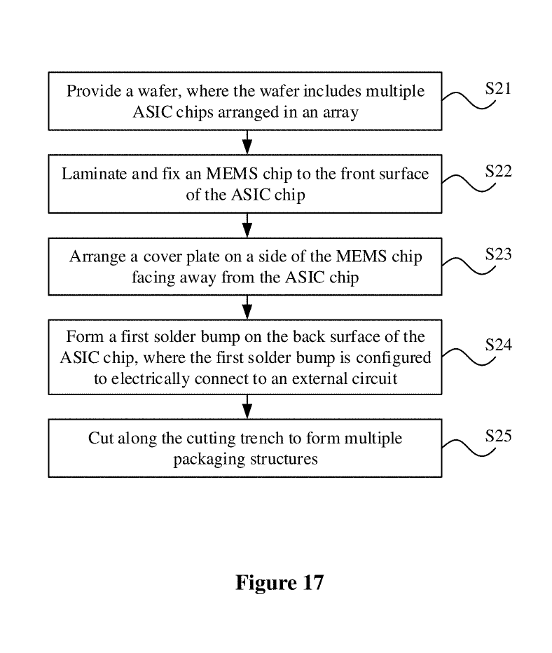

Based on the above packaging structure and chip packaging method embodiment, another chip packaging method is further provided according to an embodiment of the present disclosure, as shown as FIG. 17. FIG. 17 is a schematic flow chart of another chip packaging method for fabricating the above packaging structure according to an embodiment of the present disclosure. The chip packaging method includes steps S21 to S25.

In step S21, a wafer is provided. The wafer includes multiple ASIC chips arranged in an array, a cutting trench is arranged between two adjacent ASIC chips, and the ASIC chip has a front surface and a back surface.

In step S22, an MEMS chip is laminated and fixed to the front surface of the ASIC chip.

The MEMS chip has a front surface and a back surface opposite to each other. The front surface of the ASIC chip is laminated and fixed to the back surface of the MEMS chip, and the ASIC chip is electrically connected to the MEMS chip.

In step S23, a side of the MEMS chip facing away from the ASIC chip is provided with a cover plate.

A periphery of the cover plate is laminated and fixed to a periphery of the ASIC chip, and the cover plate is configured to seal the MEMS chip.

In step S24, a first solder bump is formed on the back surface of the ASIC chip, and the first solder bump is configured to electrically connect to an external circuit.

In step S25, cutting is performed along the cutting trench to form multiple packaging structures.

The chip packaging method shown in FIG. 17 differs from the chip packaging method shown in FIG. 6 in that the single separated cover plate is directly laminated and fixed to the MEMS chip.

In the chip packaging method shown in FIG. 17, the process of laminating and fixing an MEMS chip to the front surface of the ASIC chip includes: arranging a second solder bump on the back surface of the MEMS chip, the ASIC chip including a coupling circuit; and electrically connecting the second solder bump and the first solder bump via the coupling circuit.

In the chip packaging method shown in FIG. 17, the process of forming the first solder bump on the back surface of the ASIC chip includes: arranging a second via hole penetrating the ASIC chip on the ASIC chip; and electrically connecting the second solder bump and the first solder bump via a second conductive plug arranged in the second via hole.

In the chip packaging method shown in FIG. 17, the process of forming the first solder bump on the back surface of the ASIC chip includes: forming the second via hole penetrating the ASIC chip on the back surface of the ASIC chip, where the second contact pad 17 on the front surface of the ASIC chip is exposed from the second via hole; forming a second electrical connection structure in the second via hole 18; and forming the first solder bump 13 electrically connected to the second electrical connection structure on the back surface of the ASIC chip 11.

The second via hole is a straight hole, a double stepped hole or a trapezoidal hole.

The chip packaging method shown in FIG. 17 further includes: thinning a surface on a side of the wafer facing away from the MEMS chip. The chip packaging method shown in FIG. 17 further includes: forming a reinforcement layer on the side of the wafer facing away from the MEMS chip.

In the chip packaging method, the packaging structure of the ASIC chip and the MEMS chip is formed by adopting a wafer level packaging process. The process is simple, the cost is low, and the packaging structure is thin and has the good mechanical strength and the high integration level.

It should be noted that the embodiments in this specification are described in a progressive manner, each of which emphasizes the differences from others, and the same or similar parts among the embodiments can be referred to each other. Since the chip packaging method disclosed in the embodiments corresponds to the packaging structure disclosed in the embodiment, the description of the method is relatively simple. For relevant matters, one may refer to the description of the packaging structure.

The above description of the embodiments enables those skilled in the art to implement or use the present disclosure. Various modifications to these embodiments are apparent to those skilled in the art, and the general principle defined herein may be implemented in other embodiments without deviating from the spirit or scope of the present disclosure. Therefore, the present disclosure is not limited to these embodiments described herein, but conforms to the widest scope consistent with the principle and novel features disclosed herein.

1. A packaging structure integrated with a Micro-Electro-Mechanical System (MEMS) chip and an Application Specific Integrated Circuit (ASIC) chip, comprising:
an MEMS chip, wherein the MEMS chip has a front surface and a back surface opposite to each other;
an ASIC chip, wherein the ASIC chip has a front surface and a back surface opposite to each other, the front surface of the ASIC chip is laminated and fixed to the back surface of the MEMS chip, and the ASIC chip is electrically connected to the MEMS chip;
a first solder bump arranged on a side of the ASIC chip facing away from the MEMS chip, wherein the first solder bump is configured to electrically connect to an external circuit; and
a cover plate comprising an accommodating cavity, wherein the cover plate is arranged on the ASIC chip, the MEMS chip is located in the accommodating cavity and the cover plate is hermetically connected to the ASIC chip.

2. The packaging structure according to claim 1, wherein the back surface of the MEMS chip is provided with a second solder bump, the front surface of the MEMS chip is provided with a first contact pad electrically connected to the second solder bump; and
the ASIC chip comprises a coupling circuit configured to electrically connect to the second solder bump.

3. The packaging structure according to claim 2, wherein the back surface of the MEMS chip is provided with a first via hole penetrating the MEMS chip, the first contact pad is exposed from the first via hole; a first electrical connection structure is formed in the first via hole, and the first electrical connection structure is electrically connected to the first contact pad and the second solder bump.

4. The packaging structure according to claim 3, wherein the first electrical connection structure is a first conductive plug.

5. The packaging structure according to claim 3, wherein the first electrical connection structure comprises a first rewiring layer arranged in the first via hole.

6. The packaging structure according to claim 3, wherein an aperture of the first via hole remains unchanged in a direction from the MEMS chip to the ASIC chip;
or the aperture of the first via hole is gradually increased in a direction from the MEMS chip to the ASIC chip;
or the first via hole comprises: a groove arranged on the back surface of the MEMS chip, wherein a depth of the groove is less than a thickness of the MEMS chip; and a through hole located in the groove and penetrating the MEMS chip.

7. The packaging structure according to claim 1, wherein a second contact pad is arranged on the front surface of the ASIC chip and a second via hole penetrating the ASIC chip is arranged on the back surface of the ASIC chip, the second contact pad is exposed from the second via hole; a second connection structure is formed in the second via hole, and the second connection structure is electrically connected to the second contact pad and the first solder bump.

8. The packaging structure according to claim 7, wherein the second connection structure is a second conductive plug.

9. The packaging structure according to claim 8, wherein the second conductive plug is directly electrically connected to the first solder bump or is electrically connected to the first solder bump via a printed circuit arranged on the back surface of the ASIC chip.

10. The packaging structure according to claim 7, wherein the second connection structure comprises a second rewiring layer arranged in the second via hole.

11. The packaging structure according to claim 7, wherein an aperture of the second via hole remains unchanged in a direction from the MEMS chip to the ASIC chip;
or the aperture of the second via hole is gradually increased in a direction from the MEMS chip to the ASIC chip;
or the second via hole comprises: a groove arranged on the back surface of the MEMS chip, wherein a depth of the groove is less than a thickness of the ASIC chip; and a through hole located in the groove and penetrating the ASIC chip.

12. The packaging structure according to claim 1, wherein in a direction perpendicular to the MEMS chip and the ASIC chip, a size of the MEMS chip is less than a size of the ASIC chip.

13. The packaging structure according to claim 1, wherein the back surface of the ASIC chip is thinned and the back surface of the thinned ASIC chip is provided with a reinforcement layer.

14. A packaging method for forming a packaging structure integrated with a Micro-Electro-Mechanical System (MEMS) chip and an Application Specific Integrated Circuit (ASIC) chip, wherein the packaging structure comprises an MEMS chip, an ASIC chip, a first solder bump and a cover plate, and the packaging method comprises:
providing a wafer, wherein the wafer comprises a plurality of ASIC chips arranged in an array, a cutting trench is arranged between two adjacent ASIC chips among the plurality of ASIC chips; the ASIC chip has a front surface and a back surface;
laminating and fixing an MEMS chip to the front surface of the ASIC chip, wherein the MEMS chip has a front surface and a back surface opposite to each other; the front surface of the ASIC chip is laminated and fixed to the back surface of the MEMS chip, and the ASIC chip is electrically connected to the MEMS chip;
providing a substrate laminated and fixed to the wafer;
forming a first solder bump on the back surface of the ASIC chip, wherein the first solder bump is configured to electrically connect to an external circuit; and
cutting along the cutting trench to form a plurality of packaging structures,
wherein after the cutting, the substrate is divided into a plurality of cover plates;
each of the plurality of packaging structures has one of the plurality of cover plates; in the packaging structure, the cover plate is arranged on the ASIC chip and comprises an accommodating cavity, the MEMS chip is located in the accommodating cavity, and the cover plate is hermetically connected to the ASIC chip.

15. The packaging method according to claim 14, wherein the laminating and fixing an MEMS chip to the front surface of the ASIC chip comprises:
arranging a first contact pad on the front surface of the MEMS chip, and arranging a second solder bump electrically connected to the first contact pad on the back surface of the MEMS chip; arranging a second contact pad electrically connected to the first solder bump on the front surface of the ASIC chip; and laminating and fixing the MEMS chip to the front surface of the ASIC chip through soldering the second solder bump and the second contact pad.

16. The packaging method according to claim 15, wherein the forming the first solder bump on the back surface of the ASIC chip comprises:
forming a second via hole penetrating the ASIC chip on the back surface of the ASIC chip, wherein the second contact pad is exposed from the second via hole;
forming a second electrical connection structure in the second via hole; and
forming the first solder bump electrically connected to the second electrical connection structure on the back surface of the ASIC chip.

17. The packaging method according to claim 16, wherein the forming a second electrical connection structure in the second via hole comprises:
forming a second conductive plug or a second rewiring layer in the second via hole.

18. The packaging method according to claim 14, further comprising:
thinning a surface on a side of the wafer facing away from the MEMS chip.

19. The packaging method according to claim 18, wherein after the thinning, the method further comprises:
forming a reinforcement layer on the side of the wafer facing away from the MEMS chip.

20. A chip packaging method for forming a packaging structure integrated with a Micro-Electro-Mechanical System (MEMS) chip and an Application Specific Integrated Circuit (ASIC) chip, wherein the packaging structure comprises an MEMS chip, an ASIC chip, a first solder bump and a cover plate, and the packaging method comprises:
providing a wafer, wherein the wafer comprises a plurality of ASIC chips arranged in an array, a cutting trench is arranged between two adjacent ASIC chips among the plurality of ASIC chips; the ASIC chip has a front surface and a back surface;
laminating and fixing an MEMS chip to the front surface of the ASIC chip, wherein the MEMS chip has a front surface and a back surface opposite to each other; the front surface of the ASIC chip is laminated and fixed to the back surface of the MEMS chip, and the ASIC chip is electrically connected to the MEMS chip;
arranging a cover plate on a side of the MEMS chip facing away from the ASIC chip, wherein the cover plate comprises an accommodating cavity and is arranged on the ASIC chip, the MEMS chip is located in the accommodating cavity, and the cover plate is hermetically connected to the ASIC chip;
forming a first solder bump on the back surface of the ASIC chip, wherein the first solder bump is configured to electrically connect to an external circuit; and
cutting along the cutting trench to form a plurality of packaging structures.
